(19) United States
(12) Patent Application Publication
(10) Pub. No.: US 2024/0074187 A1
(43) Pub. Date: Feb. 29, 2024

(54) SEMICONDUCTOR DEVICE AND MANUFACTURING METHOD OF A SEMICONDUCTOR DEVICE

(71) Applicant: SK hynix Inc., Icheon-si Gyeonggi-do (KR)

(72) Inventor: Jae Taek KIM, Icheon-si Gyeonggi-do (KR)

(73) Assignee: SK hynix Inc., Icheon-si Gyeonggi-do (KR)

(21) Appl. No.: 18/092,790

(22) Filed: Jan. 3, 2023

(30) Foreign Application Priority Data
Aug. 26, 2022 (KR) 10-2022-0107612

(51) Int. Cl. H10B 43/27; H01L 23/528; H10B 41/10; H10B 41/27; H10B 43/10

(52) U.S. Cl. CPC H10B 43/27; H01L 23/5283; H10B 41/10; H10B 41/27; H10B 43/10

(57) ABSTRACT

A semiconductor device includes a gate structure including word lines and select lines, the gate structure including a first pad stepped structure for exposing each of the select lines and a common pad structure for exposing the select lines. The semiconductor device also includes first contact plugs connected to the select lines through the first pad stepped structure, respectively. The semiconductor device further includes one or more common contact plugs connected in common to the select lines through the common pad structure.

### CROSS-REFERENCE TO RELATED APPLICATION

This application claims priority under 35 U.S.C. § 119 to Korean Patent Application No. 10-2022-0107612 filed on Aug. 26, 2022, in the Korean Intellectual Property Office, which is incorporated herein by reference in its entirety.

### BACKGROUND

### 1. Technical Field

Embodiments of the present disclosure relate to an electronic device, and more particularly, to a semiconductor device and a manufacturing method of a semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, to improve the operational reliability of such a semiconductor device, various structures and manufacturing methods have been developed.

### SUMMARY

In an embodiment, a semiconductor device may include: a gate structure including word lines and select lines, the gate structure including a first pad stepped structure for exposing each of the select lines and a common pad structure for exposing the select lines; contact plugs connected to the select lines through the first pad stepped structure, respectively; and one or more common contact plugs connected in common to the select lines through the common pad structure.

In an embodiment, a semiconductor device may include: a gate structure including a first gate line and a second gate line; a first contact plug connected to the first gate line; a second contact plug connected to the second gate line; and a common contact plug connected in common to the first gate line and the second gate line. A bias is applied in common to the first gate line and the second gate line through the first contact plug, the second contact plug, and the common contact plug.

In accordance with the present disclosure, a manufacturing method of a semiconductor device may include: forming a stack including first material layers and second material layers that are alternately stacked; forming a first pad stepped structure exposing each of the first material layers in the stack; forming a common pad structure exposing the first material layers in the stack; forming contact plugs respectively connected to the first material layers through the first pad stepped structure; and forming one or more common contact plugs connected in common to the first material layers through the common pad structure.

### BRIEF DESCRIPTION OF THE DRAWINGS

FIG. 1 is a diagram for describing the structure of a semiconductor device in accordance with an embodiment.

FIG. 2A and FIG. 2B are diagrams illustrating the structure of a semiconductor device in accordance with an embodiment.

FIG. 3A and FIG. 3B, FIG. 4A and FIG. 4B, FIG. 5A and FIG. 5B, FIG. 6A and FIG. 6B, FIG. 7A and FIG. 7B, FIG. 8A and FIG. 8B, and FIG. 9A and FIG. 9B are diagrams for describing a manufacturing method of a semiconductor device in accordance with an embodiment.

### DETAILED DESCRIPTION

Various embodiments are directed to a semiconductor device having a stable structure and improved characteristics and a manufacturing method thereof.

By stacking memory cells in three dimensions, it is possible to improve the degree of integration of a semiconductor device. Furthermore, it is possible to provide a semiconductor device having a stable structure and improved reliability.

Hereafter, embodiments in accordance with the technical spirit of the present disclosure will be described with reference to the accompanying drawings.

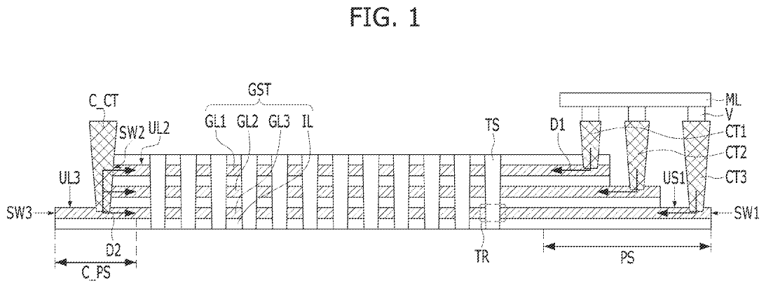

FIG. 1 is a diagram for describing the structure of a semiconductor device in accordance with an embodiment.

Referring to FIG. 1, the semiconductor device may include a gate structure GST, contact plugs CT1 to CT3, and at least one common contact plug C_CT. The semiconductor device may further include a through structure TS, a wiring line ML, or vias V, or may further include a combination thereof.

The gate structure GST may include gate lines GL1 to GL3. The gate lines GL1 to GL3 may be select lines, word lines, or bit lines. In an embodiment, the gate lines GL1 to GL3 may be source select lines or drain select lines. The gate structure GST may further include insulating layers IL alternately stacked with the gate lines GL1 to GL3. The insulating layers IL are used to insulate the gate lines GL1 to GL3 from each other and may include an insulating material such as an oxide, a nitride, or an air gap.

The gate structure GST may include a pad stepped structure PS and a common pad structure C_PS. The pad stepped structure PS and the common pad structure C_PS may be located to face each other with the through structure TS interposed therebetween. The pad stepped structure PS and the common pad structure C_PS may be asymmetrical to each other.

The pad stepped structure PS may expose each of the gate lines GL1 to GL3. In an embodiment, the pad stepped structure PS may have a structure in which first sidewalls SW1 of the gate lines GL1 to GL3 are spaced apart from each other. The gate lines GL1 to GL3 may include a first upper surface US1 connected to the first sidewall SW1. The first upper surfaces US1 of the gate lines GL1 to GL3 may be exposed by the pad stepped structure PS, respectively. Accordingly, the first upper surfaces US1 may be used as pads electrically connected to contact plugs CT1 to CT3.

The common pad structure C_PS may expose the gate lines GL1 to GL3. In an embodiment, second sidewalls SW2 of the gate lines GL1 and GL2 may be exposed by the common pad structure C_PS, and the common pad structure C_PS may have a structure in which the second sidewalls SW2 are aligned with each other. The second sidewalls SW2 may be located on the same plane and may be commonly exposed on a common plane. Second upper surfaces US2 connected to the second sidewalls SW2 might not be exposed. Accordingly, the second sidewalls SW2 may be used as pads electrically connected to the common contact plug C_CT.

For reference, an upper surface US3 of at least one of the commonly connected gate lines GL1 to GL3 may be exposed. In an embodiment, in the case of a third gate line GL3 that is the lowermost select line of the select lines, a third upper surface US3 connected to the second sidewall SW2 may be exposed by the common pad structure C_PS. Accordingly, the third upper surface US3 may be used as a pad electrically connected to the common contact plug C_CT.

The contact plugs CT1 to CT3 may be connected to the gate lines GL1 to GL3, respectively. The contact plugs CT1 to CT3 may be connected to the upper surfaces US1 of the gate lines GL1 to GL3 exposed through the pad stepped structure PS, respectively. A first contact plug CT1 may be connected to a first gate line GL1, a second contact plug CT2 may be connected to a second gate line GL2, and a third contact plug CT3 may be connected to the third gate line GL3.

The contact plugs CT1 to CT3 may be connected to the vias V, respectively, and may be electrically connected to the wiring line ML through the vias V. The contact plugs CT1 to CT3 may be electrically connected to the same wiring line ML.

The common contact plug C_CT may be connected in common to the gate lines GL1 to GL3. The common contact plug C_CT may be connected in common to the second sidewalls SW2 of the gate lines GL1 and GL2. When the third gate line GL3 is the lowermost select line among the select lines, the common contact plug C_CT may be connected in common to the second sidewalls SW2 of the first gate line GL1 and the second gate line GL2 and the third upper surface US3 of the third gate line GL3.

The through structure TS may pass through the gate structure GST. The through structure TS may be located between the pad stepped structure PS and the common pad structure C_PS. The through structure TS may be located between the first contact plug CT1 and the common contact plug C_CT. The through structure TS may be a channel structure or an electrode structure. In an embodiment, the channel structure may include a channel layer passing through the gate structure GST, a memory layer surrounding a sidewall of the channel layer, or an insulating core in the channel layer, or a combination thereof. The electrode structure may include an electrode layer passing through the gate structure GST or a memory layer surrounding an outer wall or an inner wall of the electrode layer, or a combination thereof.

Transistors TR may be located in regions where the through structure TS and the gate lines GL1 to GL3 intersect with each other. A first transistor may be located at an intersection region of the first gate line GL1 and the through structure TS, a second transistor may be located at an intersection region of the second gate line GL2 and the through structure TS, and a third transistor may be located at an intersection region of the third gate line GL3 and the through structure TS. When the gate lines GL1 to GL3 are select lines, the transistors TR may be select transistors. When the gate lines GL1 to GL3 are word lines or bit lines, the transistors TR may be memory cells.

According to the structure described above, when the gate lines GL1 to GL3 are operated, a bias may be is applied to the gate lines GL1 to GL3 in common. the contact plugs CT1 to CT3 may be connected to one sides of the gate lines GL1 to GL3, respectively, and the common contact plug C_CT may be connected in common to the other sides of the gate lines GL1 to GL3. Accordingly, the gate lines GL1 to GL3 may be connected in parallel to reduce resistances of the gate lines GL1 to GL3.

When a bias is applied to the gate lines GL1 to GL3 to drive the transistors TR, the bias applied through the contact plugs CT1 to CT3 may be transferred not only in a first direction D1 but also in a second direction D2 through the common contact plug C_CT. Accordingly, a bias may be applied in common to the gate lines GL1 to GL3 connected in parallel, and operating speeds of the transistors TR may be improved.

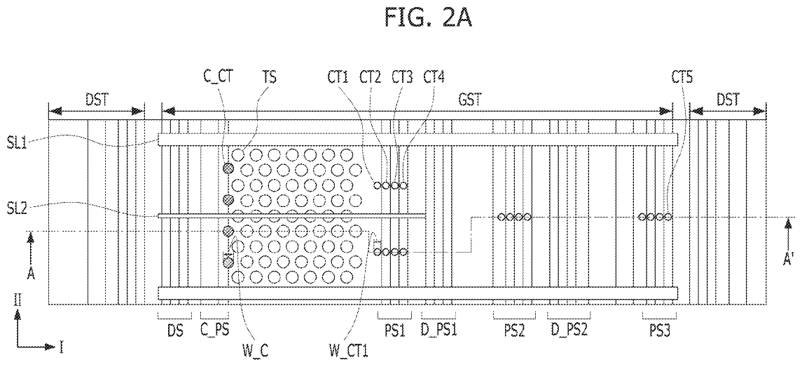

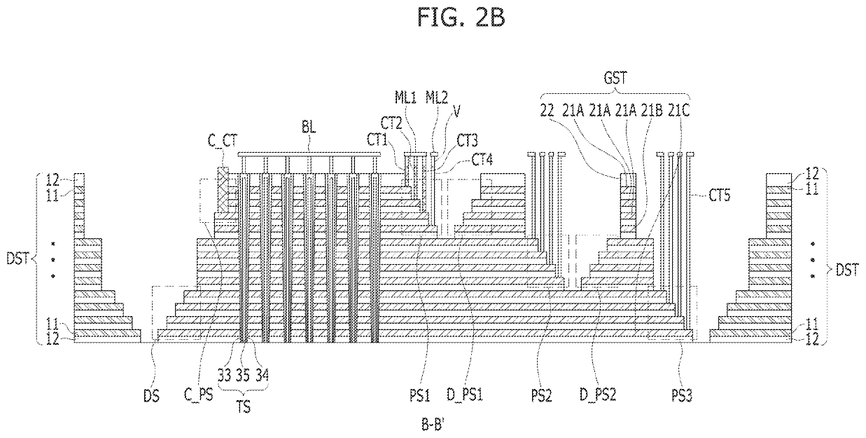

FIGS. 2A and 2B are diagrams illustrating the structure of a semiconductor device according to an embodiment. FIG. 2A may be a plan view and FIG. 2B may be a cross-sectional view taken along line A-A′ in FIG. 2A. Hereinafter, content redundant with the previously described content may be omitted.

Referring to FIG. 2A and FIG. 2B, the semiconductor device may include a gate structure GST, contact plugs CT1 to CT5, and at least one common contact plug C_CT. The semiconductor device may further include dummy stacks DST, a through structure TS, a first wiring line ML1, second wiring lines ML2, or vias V, or a combination thereof.

The gate structure GST may be located on the base 10. The base 10 may include a lower structure such as a substrate, a source structure, and a peripheral circuit. The gate structure GST may include conductive layers 21A to 21C and insulating layers 22 that are alternately stacked. The conductive layers 21A to 21C may be select lines, word lines, or bit lines. In an embodiment, at least one first conductive layer 21A that is the uppermost layer of the conductive layers 21A to 21C may be a drain select line, at least one third conductive layer 21C that is the lowermost layer of the conductive layers 21A to 21C may be a source select line, and the remaining second conductive layers 21B may be word lines. For reference, a source and a drain are relative concepts, and at least one first conductive layer 21A that is the uppermost layer of the conductive layers 21A to 21C may be a source select line, and at least one third conductive layer 21C that is the lowermost layer of the conductive layers 21A to 21C may be a drain select line.

The gate structure GST may include a first pad stepped structure PS1 and a common pad structure C_PS. The first pad stepped structure PS1 and the common pad structure C_PS may be located to face each other with the through structure TS interposed therebetween. The first pad stepped structure PS1 may expose the first conductive layers 21A used as drain select lines. For reference, the first pad stepped structure PS1 may also expose at least one of the second conductive layers 21B used as word lines.

The gate structure GST may further include a second pad stepped structure PS2 or a third pad stepped structure PS3, or a combination thereof. The first pad stepped structure PS1, the second pad stepped structure PS2, and the third pad stepped structure PS3 may be located at different levels. The second pad stepped structure PS2 or the third pad stepped structure PS3 may have substantially the same stepped shape as the first pad stepped structure PS1.

The second pad stepped structure PS2 may be located to face the common pad structure C_PS with the first pad stepped structure PS1 interposed therebetween. The second pad stepped structure PS2 may expose the second conductive layers 21B used as word lines. For reference, the second pad stepped structure PS2 may also expose at least one of the third conductive layer 21C used as source select lines.

The third pad stepped structure PS3 may be located to face the common pad structure C_PS with the first pad stepped structure PS1 or the second pad stepped structure PS2 interposed therebetween. The third pad stepped structure PS3 may expose the third conductive layers 21C used as source select lines. For reference, the third pad stepped structure PS3 may also expose at least one of the second conductive layer 21B used as word lines.

The gate structure GST may further include a first dummy pad stepped structure D_PS1 or a second dummy pad stepped structure D_PS2, or a combination thereof. The first dummy pad stepped structure D_PS1 may be located at substantially the same level as the first pad stepped structure PS1, may be located to face the first pad stepped structure PS1, and may be symmetrical to the first pad stepped structure PS1. The second dummy pad stepped structure D_PS2 may be located at substantially the same level as the second pad stepped structure PS2, may be located to face the second pad stepped structure PS2, and may be symmetrical to the second pad stepped structure PS2.

The gate structure GST may further include a dummy stepped structure DS connected to the common pad structure C_PS. The dummy stepped structure DS may be located at substantially the same level as the third pad stepped structure PS3, may be located to face the third pad stepped structure PS3 with the through structure TS interposed therebetween, and may be symmetrical to the third pad stepped structure PS3. The dummy stepped structure DS may expose the third conductive layers 21C used as source select lines. For reference, the dummy stepped structure DS may also expose at least one of the second conductive layers 21B used as word lines.

The gate structure GST may further include a first slit structure SL1 or a second slit structure SL2, or a combination thereof. The first slit structure SL1 may expand in a first direction I and pass through the gate structure GST in a third direction III. The third direction III may be a direction protruding from a plane defined by the first direction I and a second direction II. In an embodiment, the gate structure GST may be separated in units of memory blocks by the first slit structure SL1. The second slit structure SL2 may be located in the gate structure GST and may have a depth by which the first conductive layers 21A are passed through. Accordingly, the drain select lines may have a narrower width than the word lines. The second slit structure SL2 may expand in the first direction I and may cross the through structure TS.

The contact plugs CT1 to CT5 may be connected to the conductive layers 21A to 21C, respectively. In an embodiment, first to third contact plugs CT1 to CT3 may be connected to the first conductive layers 21A used as drain select lines, respectively. Fourth contact plugs CT4 may be connected to the second conductive layers 21B used as word lines, respectively. The fifth contact plugs CT5 may be connected to the third conductive layers 21C used as source select lines, respectively.

The first to fifth contact plugs CT1 to CT5 may be connected to first to third wiring lines ML3 through the vias V. The first to third contact plugs CT1 to CT3 may be connected in common to the first wiring line ML1. The fourth contact plugs CT4 may be connected to the second wiring lines ML2, respectively. The fifth contact plugs CT5 may be respectively connected to or connected in common to the third wiring lines ML3. The common contact plug C_CT may be connected in common to some of the conductive layers 21A to 21C. In an embodiment, the common contact plug C_CT may be connected in common to the first conductive layers 21A used as drain select lines.

The first to third contact plugs CT1 to CT3 and the common contact plug C_CT may be located at substantially the same level. The first to third contact plugs CT1 to CT3 and the common contact plug C_CT may have substantially the same width or different widths. In an embodiment, the common contact plug C_CT may have a greater width (W_C>W_CT1) than the first to third contact plugs CT1 to CT3.

The first to third contact plugs CT1 to CT3 may be arranged in the first direction I, and the common contact plugs C_CT may be arranged in the second direction II intersecting the first direction I. Intersecting directions refers to different directions. In some embodiments, intersecting directions are perpendicular directions. The first to fifth contact plugs CT1 to CT5 might not be connected to the first dummy pad stepped structure D_PS1, the second dummy stepped structure D_PS1, or the dummy stepped structure DS.

The through structure TS may pass through the gate structure GST between the first pad stepped structure PS1 and the common pad structure C_PS. The through structure TS may be connected to the bit line BL through the via V. The bit line BL may be located at substantially the same level as the first wiring line ML1 or the second wiring line ML2.

The dummy stack DST may be located on the base 10 and may include first material layers 11 and second material layers 12 that are alternately stacked. The gate structure GST may be located between a pair of dummy stacks DST. The first material layers 11 may each include a material having a high etch selectivity with respect to the second material layers 12. For example, the first material layers 11 may each include a sacrificial material such as a nitride, and the second material layers 12 may each include an insulating material such as an oxide. In another example, the first material layers 11 may each include a conductive material such as polysilicon, tungsten, or molybdenum, and the second material layers 12 may each include an insulating material such as an oxide. The first material layers 11 may remain without being replaced with the conductive layers 21A to 21C during a manufacturing process.

According to the structure described above, drain select transistors may be located in an intersection region between the through structure TS and the first conductive layers 21A. During the operation of the drain select transistors, a bias may be applied in common to the first conductive layers 21A through the first to third contact plugs CT1 to CT3 and the common contact plug C_CT. Accordingly, resistance may be improved by connecting the first conductive layers 21A in parallel, and operation characteristics of the drain select transistors may be improved.

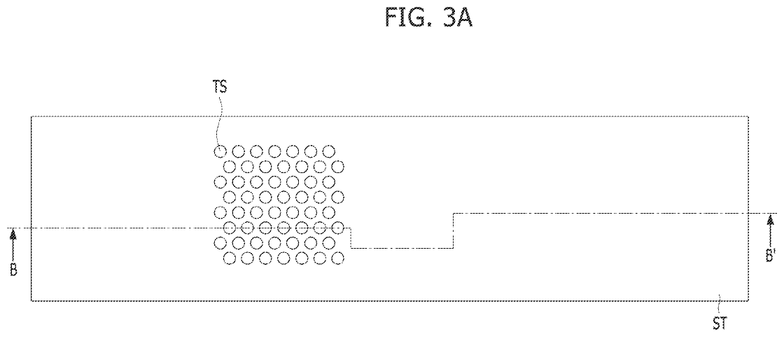

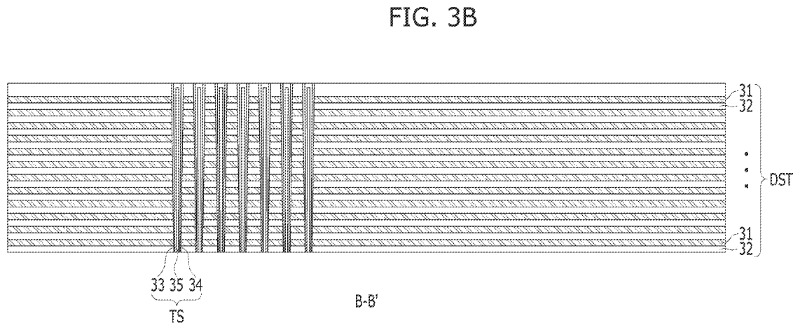

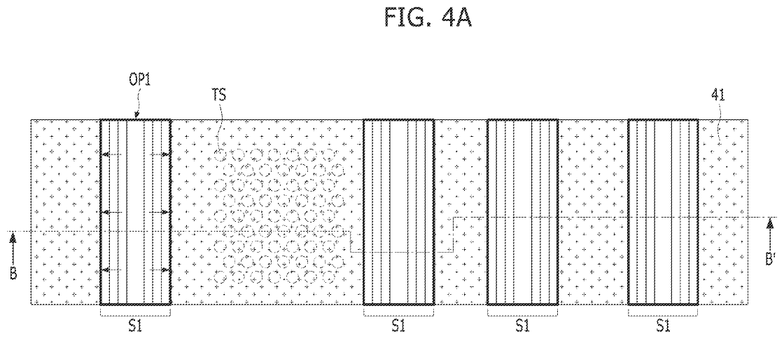

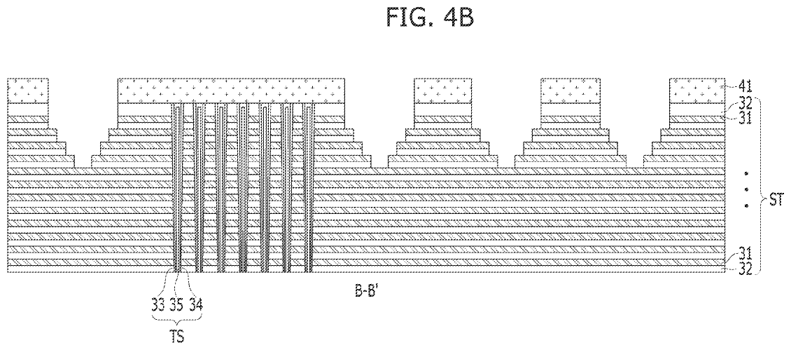

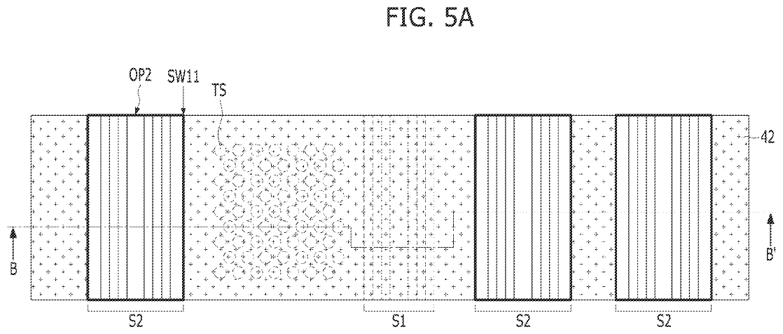

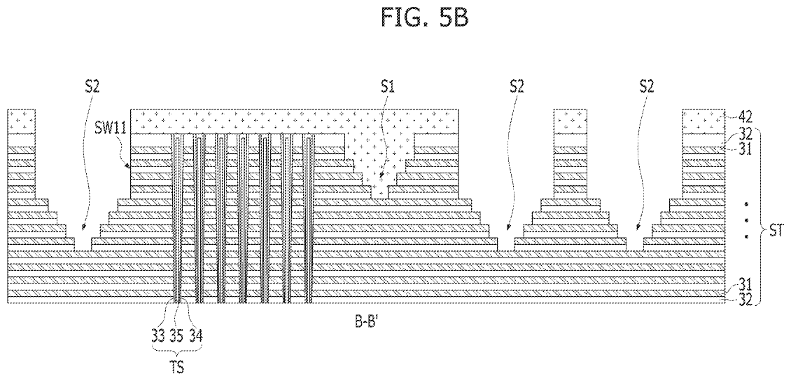

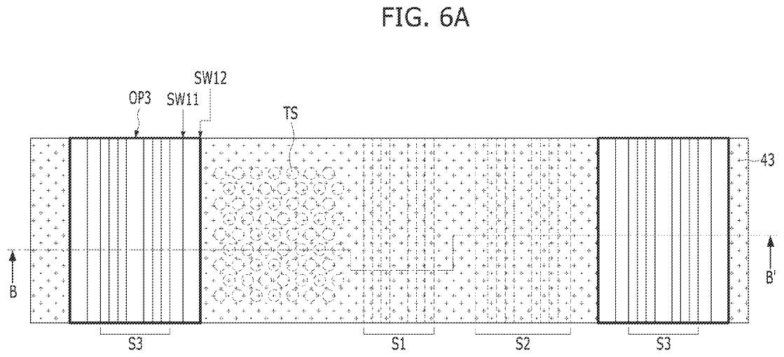

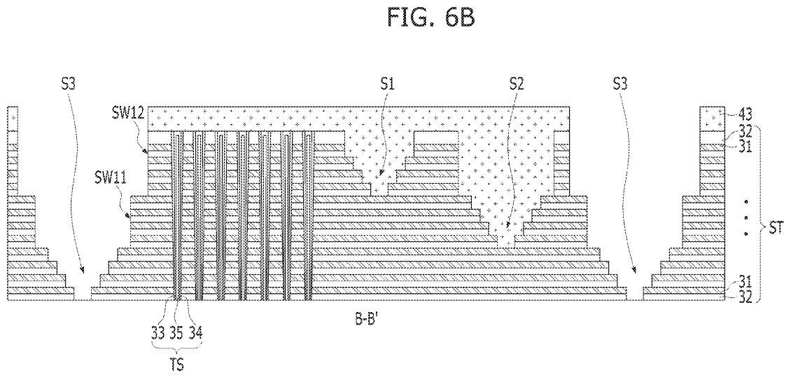

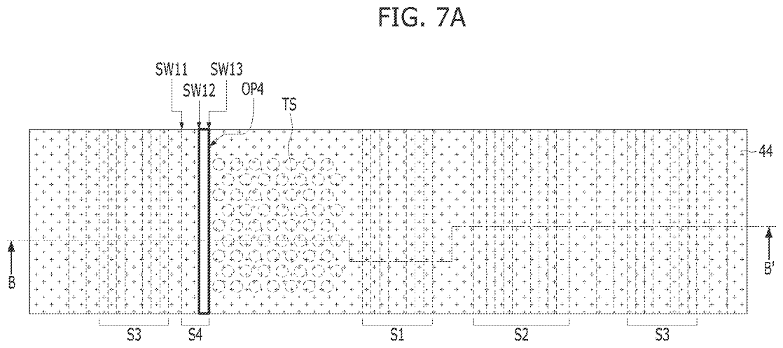

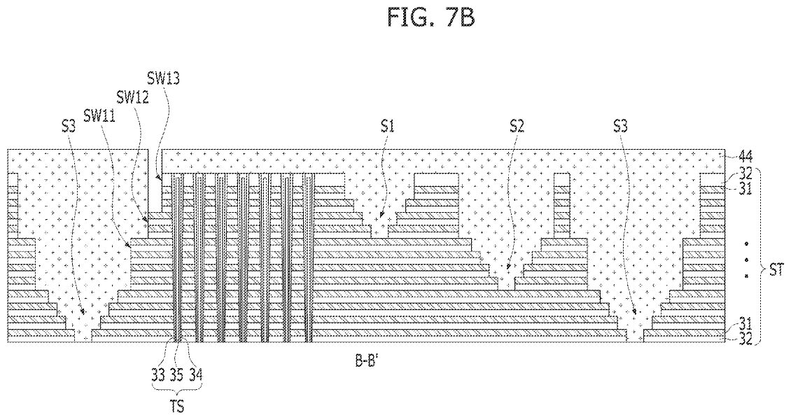

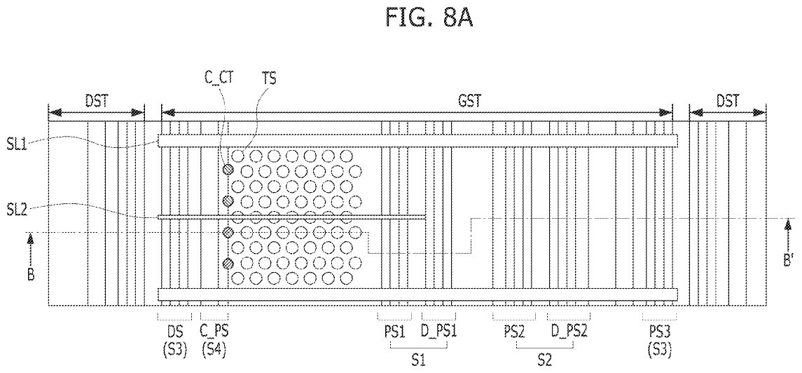

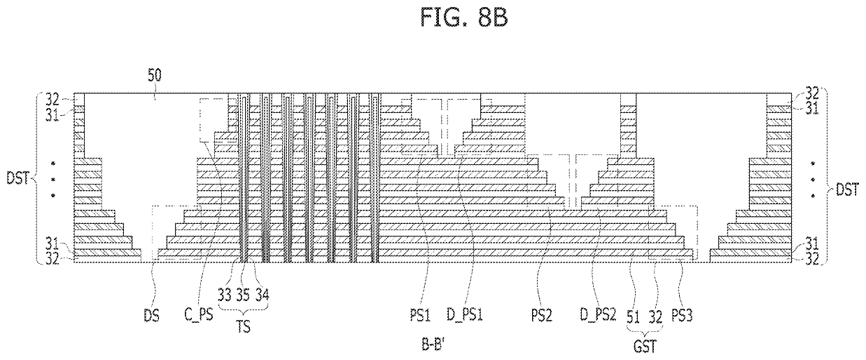

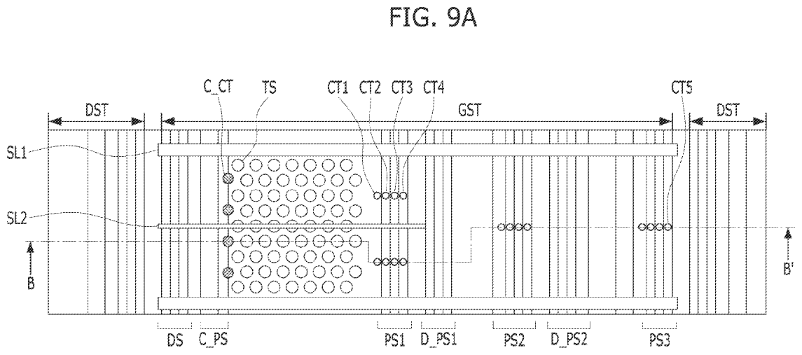

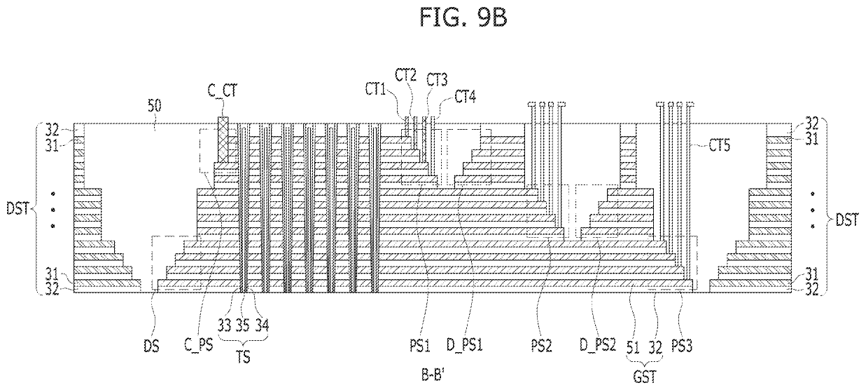

FIG. 3A and FIG. 3B, FIG. 4A and FIG. 4B, FIG. 5A and FIG. 5B, FIG. 6A and FIG. 6B, FIG. 7A and FIG. 7B, FIG. 8A and FIG. 8B, and FIG. 9A and FIG. 9B are diagrams for describing a manufacturing method of a semiconductor device in accordance with an embodiment. FIG. 3A, FIG. 4A, FIG. 5A, FIG. 6A, FIG. 7A, FIG. 8A, and FIG. 9A may be plan views, and FIG. 3B, FIG. 4B, FIG. 5B, FIG. 6B, FIG. 7B, FIG. 8B, and FIG. 9B may be sectional views taken along lines B-B′ in FIG. 3A to FIG. 9A. Hereinafter, content redundant with the previously described content may be omitted.

Referring to FIG. 3A and FIG. 3B, a stack ST may be formed. The stack ST may include first material layers 31 and second material layers 32 that are alternately stacked. The first material layers 31 may be used to form word lines, bit lines, select lines, and the like, and the second material layers 32 may be used to form an insulating layer. The first material layers 31 may each include a material having a high etch selectivity with respect to the second material layers 32. For example, the first material layers 31 may each include a sacrificial material such as a nitride, and the second material layers 32 may each include an insulating material such as an oxide. In another example, the first material layers 31 may each include a conductive material such as polysilicon, tungsten, or molybdenum, and the second material layers 32 may each include an insulating material such as an oxide.

Subsequently, through structures TS passing through the stack ST may be formed. The through structures TS may each be a channel structure or an electrode structure. In an embodiment, the channel structure may include a channel layer 33, and may further include a memory layer 34 or an insulating core 35. The memory layer 34 may surround a sidewall of the channel layer 33. The memory layer 34 may include a tunneling layer, a data storage layer, a blocking layer, or a combination thereof. The data storage layer may include a floating gate, polysilicon, a charge trap material, a nitride, a variable resistance material, or the like, or a combination thereof.

Referring to FIG. 4A and FIG. 4B, first stepped structures S1 may be formed. In an embodiment, a first mask pattern 41 may be formed on the stack ST. The first mask pattern 41 may cover the through structures TS and include first openings OP1 for exposing a region where the first stepped structures S1 are to be formed. Subsequently, the stack ST may be etched using the first mask pattern 41 as an etch barrier. Subsequently, after the first openings OP1 are expanded (see arrows in FIG. 4A), the stack ST is etched using the first mask pattern 41 as an etch barrier. As described above, the first stepped structures S1 may be formed by alternately repeating the expansion of the first openings OP1 and the etching of the stack ST. The first stepped structures S1 may expose the uppermost one or more first material layers 31, respectively. In an embodiment, the first stepped structures S1 may expose the first material layers 31 corresponding to the drain select lines, respectively. Subsequently, the first mask pattern 41 may be removed.

Referring to FIG. 5A and FIG. 5B, second stepped structures S2 may be formed. At least one of the first stepped structures S1 may be transferred into the stack ST to form the second stepped structures S2. In an embodiment, a second mask pattern 42 may be formed on the stack ST. The second mask pattern 42 may include second openings OP2 for exposing at least one of the first stepped structures S1. Subsequently, the stack ST may be etched using the second mask pattern 42 as an etch barrier to form the second stepped structures S2. The second openings OP2 may each have a wider width than the first openings OP1. Accordingly, first sidewalls SW11 connected to the second stepped structures S2 may be defined. Subsequently, the second mask pattern 42 may be removed.

Referring to FIG. 6A and FIG. 6B, third stepped structures S3 may be formed. At least one of the second stepped structures S2 may be transferred into the stack ST to form the third stepped structures S3. In an embodiment, a third mask pattern 43 may be formed on the stack ST. The third mask pattern 43 may include third openings OP3 for exposing at least one of the second stepped structures S2. Subsequently, the stack ST may be etched using the third mask pattern 43 as an etch barrier to form the third stepped structures S3. The third openings OP3 may each have a wider width than the first openings OP1 or the second openings OP2. Accordingly, second sidewalls SW12 connected to the first sidewalls SW11 may be defined. Subsequently, the third mask pattern 43 may be removed.

Referring to FIG. 7A and FIG. 7B, a fourth stepped structure S4 may be formed. The second sidewall SW12 connected to at least one of the third stepped structures S3 may be partially retracted to form a third sidewall SW13. The third sidewall SW13 may be connected to the second sidewall SW12 and located between the second sidewall SW12 and the through structure TS. In an embodiment, a fourth mask pattern 44 may be formed on the stack ST. The fourth mask pattern 44 may include a fourth opening OP4 for exposing the stack ST by a predetermined interval from the second sidewall SW12. The fourth mask pattern may be formed to cover the through structures TS, and the fourth opening OP4 may be spaced apart from the through structures TS. Subsequently, the stack ST may be etched using the fourth mask pattern 44 as an etch barrier to form the third sidewall SW3. Due to the difference in distance between the second sidewall SW12 and the third sidewall SW13, the fourth stepped structure S4 may be formed. Subsequently, the fourth mask pattern 44 may be removed.

Referring to FIG. 8A and FIG. 8B, after an insulating layer 50 is formed on the stack ST to cover the first to fourth stepped structures S1 to S4, a first slit structure SL1 passing through the stack ST may be formed. In an embodiment, after a first slit passing through the stack ST and the insulating layer 50 is formed, the first material layers 31 exposed through the first slit may be replaced with conductive layers 51. Accordingly, a gate structure GST including the conductive layers 51 and the second material layers 32 that are alternately stacked may be formed. When the first material layers 31 are replaced with the conductive layers 51, some of the first material layers 31 may remain without being replaced. Accordingly, a dummy stack DST including the first material layers 31 and the second material layers 32 that are alternately stacked may be formed.

The gate structure GST may include a first pad stepped structure PS1 and a first dummy pad stepped structure D_PS1 defined by the first stepped structure S1. The gate structure GST may include a second pad stepped structure PS2 and a second dummy pad stepped structure D_PS2 defined by the second stepped structure S2. The gate structure GST may include a third pad stepped structure PS3 defined by the third stepped structure S3. The gate structure GST may include a dummy stepped structure DS defined by the third stepped structure S3. The gate structure GST may include a common pad structure C_PS defined by the fourth stepped structure S4.

The first pad stepped structure PS1, the second pad stepped structure PS2, and the third pad stepped structure PS3 may be located on one side of the through structures TS and expose one side of the conductive layers 51. The common pad stepped structure C_PS may be located on the other side of the through structures TS, and may commonly expose the other side of the uppermost one or more conductive layers 51. The first pad stepped structure PS1 and the common pad structure C_PS may be located to face each other with the through structures TS interposed therebetween.

Subsequently, a first slit structure SL1 may be formed in the first slit. In an embodiment, the first slit structure SL1 may include a source contact structure. Subsequently, a second slit structure SL2 may be formed in the gate structure GST. The second slit structure SL2 may pass through the conductive layers 51 corresponding to drain select lines among the conductive layers 51. The second slit structure SL2 may cross the through structure TS and expand in one direction.

Referring to FIG. 9A and FIG. 9B, contact plugs CT1 to CT5 and a common contact plug C_CT may be formed. The contact plugs CT1 to CT5 may be located on one side of the through structures TS and be connected to the conductive layers 51 exposed through the first pad stepped structure PS1, the second pad stepped structure PS2, and the third pad stepped structure PS3, respectively. In an embodiment, the first to third contact plugs CT1 to CT3 may be connected to drain select lines, respectively, the fourth contact plugs CT4 may be connected to word lines, respectively, and the fifth contact plug CT5 may be connected to source select lines, respectively.

The common contact plug C_CT may be located on the other side of the through structures TS and may be connected in common to the conductive layers 51 exposed through the common pad structure C_PS. In an embodiment, the common contact plug C_CT may be connected in common to the drain select lines.

According to the manufacturing method described above, one side of the conductive layers 51 may be exposed through the first pad stepped structure SP1, and the other side of the conductive layers 51 may be commonly exposed through the common pad structure C_PS. Accordingly, by connecting the first to third contact plugs CT1 to CT3 to one side of the conductive layers 51, respectively, and commonly connecting the common contact plug C_CT to the other side of the conductive layers 51, the conductive layers 51 may be connected in parallel.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including word lines and select lines, the gate structure including a first pad stepped structure for exposing each of the select lines and a common pad structure for exposing the select lines;
contact plugs connected to the select lines through the first pad stepped structure, respectively; and
one or more common contact plugs connected in common to the select lines through the common pad structure.

2. The semiconductor device of claim 1, wherein the first pad stepped structure has a structure in which first sidewalls of the select lines are spaced apart from each other.

3. The semiconductor device of claim 1, wherein the contact plugs are connected to upper surfaces of the select lines exposed through the first pad stepped structure, respectively.

4. The semiconductor device of claim 1, wherein the common pad structure has a structure in which second sidewalls of the select lines are aligned with each other.

5. The semiconductor device of claim 1, wherein the common contact plugs are connected in common to second sidewalls of the select lines.

6. The semiconductor device of claim 1, wherein the common pad structure has a structure in which an upper surface of a lowermost select line among the select lines is exposed, and second sidewalls of remaining select lines are aligned with each other.

7. The semiconductor device of claim 6, wherein the common contact plugs are connected in common to the upper surface of the lowermost selection line and the second sidewalls of the remaining selection lines.

8. The semiconductor device of claim 1, wherein the common contact plug has a greater width than widths of the contact plugs.

9. The semiconductor device of claim 1, wherein the contact plugs are arranged in a first direction, and the common contact plugs are arranged in a second direction intersecting the first direction.

10. The semiconductor device of claim 1, wherein the gate structure includes a second pad stepped structure,
wherein the second pad stepped structure is located to face the common pad structure with the first pad stepped structure interposed between the second pad stepped structure and the common pad structure, and
wherein the second pad stepped structure exposes the word lines, respectively.

11. The semiconductor device of claim 10, wherein the gate structure includes a dummy stepped structure,
wherein the dummy stepped structure is connected to the common pad structure, and
wherein the dummy stepped structure exposes the word lines, respectively.

12. The semiconductor device of claim 1, further comprising:
channel structures located between the first pad stepped structure and the common pad structure, the channel structures passing through the gate structure.

13. The semiconductor device of claim 12, wherein select transistors are located in a region where the channel structures and the selection lines intersect with each other.

14. The semiconductor device of claim 13, wherein a bias is applied in common to the selection lines through the contact plugs and the common contact plug when the select transistors are operated.

15. A semiconductor device comprising:
a gate structure including a first gate line and a second gate line;
a first contact plug connected to the first gate line;
a second contact plug connected to the second gate line; and
a common contact plug connected in common to the first gate line and the second gate line,
wherein a bias is applied in common to the first gate line and the second gate line through the first contact plug, the second contact plug, and the common contact plug when the first gate line and the second gate line are operated.

16. The semiconductor device of claim 15, wherein the gate structure comprises:
a pad stepped structure exposing the first gate line and the second gate line, respectively; and
a common pad structure exposing the first gate line and the second gate line.

17. The semiconductor device of claim 15, further comprising:
a channel structure located between the first contact plug and the common contact plug, the channel structure passing through the gate structure.

18. The semiconductor device of claim 17, further comprising:
a first transistor located at an intersection region of the channel structure and the first gate line; and
a second transistor located at an intersection region of the channel structure and the second gate line.

19. The semiconductor device of claim 18, wherein the first transistor and the second transistor are commonly driven by the bias.

20. The semiconductor device of claim 15, wherein the first gate line and the second gate line each are a drain select line or a source select line.

21. A manufacturing method of a semiconductor device, the manufacturing method comprising:
forming a stack including first material layers and second material layers that are alternately stacked;
forming a first pad stepped structure exposing each of the first material layers in the stack;
forming a common pad structure exposing the first material layers in the stack;
forming contact plugs respectively connected to the first material layers through the first pad stepped structure; and
forming one or more common contact plugs connected in common to the first material layers through the common pad structure.

22. The manufacturing method of claim 21, wherein forming the common pad structure comprises:
forming first stepped structures exposing the first material layers, respectively;
forming second stepped structures by transferring some of the first stepped structures into the stack; and
forming the common pad structure connected to one of the second stepped structures.

23. The manufacturing method of claim 22, wherein the second stepped structures each include a second pad stepped structure exposing each of the first material layers.

24. The manufacturing method of claim 22, further comprising:
forming third stepped structures by transferring at least one of the second stepped structures into the stack.

25. The manufacturing method of claim 24, wherein the third stepped structures each include a third pad stepped structure exposing each of the first material layers.

26. The manufacturing method of claim 24, wherein the third stepped structures each include a dummy stepped structure connected to the common pad structure.

27. The manufacturing method of claim 21, wherein the first pad stepped structure has a structure in which first sidewalls of the first material layers are spaced apart from each other.

28. The manufacturing method of claim 27, wherein the contact plugs are connected to upper surfaces of the first material layers exposed through the first pad stepped structure, respectively.

29. The manufacturing method of claim 21, wherein the common pad stepped structure has a structure in which second sidewalls of the first material layers are aligned with each other.

30. The manufacturing method of claim 21, further comprising:
forming a channel structure passing through the stack.

31. The manufacturing method of claim 30, wherein the first pad stepped structure and the common pad structure are located to face each other with the channel structure interposed therebetween.
